(19) United States
(12) Patent Application Publication
(10) Pub. No.: US 2007/0095564 A1
(43) Pub. Date: May 3, 2007

(54) Thin printed circuit board

(76) Inventors: Ron Kozenitzky, Petach Tikva (IL); Yanki Margalit, Ramat-Gan (IL)

Correspondence Address: DR. MARK FRIEDMAN LTD.;C/O Mr. Bill Polkinghorn, 9003 Florin Way, Upper Marlboro, MD, 20772, US

(21) Appl. No.: 11/264,161

(22) Filed: Nov. 2, 2005

(51) Int. Cl. H05K 1/16

(52) U.S. Cl. 174/260

(57) ABSTRACT

The present invention is directed to a printed circuit board, comprising: at least one chip; and a board comprising at least one aperture corresponding to each chip, for enabling each chip to be placed inside the corresponding aperture, thereby enabling reducing the thickness of the printed circuit board to that of the thickest chip. According to one embodiment of the invention, the chip is placed on the board with the upper side of the chip up. According to another embodiment of the invention, the chip is placed on the board with the upper side of the chip down. According to one embodiment of the invention the legs of the chip have “straight” form. According to another embodiment of the invention the legs of the chip have “bent” form.

### FIELD OF THE INVENTION

The present invention relates to the field of mounting chips on printed circuit boards.

### BACKGROUND OF THE INVENTION

The term Integrated Circuit (IC) refers in the art as to a microelectronic semiconductor device consisting of many interconnected transistors and other electronic components. ICs are constructed on a small rectangle cut from a Silicon (or for special applications, Sapphire) wafer. Integrated circuits are also known as “Chips”.

The term Printed Circuit Board (PCB) refers in the art as to a printed board on which chips and other electronic components are placed.

The term Chip Mount Technology refers in the art as to a technology of electronic assembly manufacturing, such as TOB, COB or Flip chip, which connects bare integrated circuit to a printed board (substrate). There are several types of flip chip mounting methods, each one focused in a different aspect, such as low cost performance, high bonding temperature, bonding reliability, process flexibility, etc.

As the currently popular products, such as cellular telephones, PDAs, and laptop computers, get smaller, decreasing the thickness of a PCB becomes an essential issue. Nevertheless the methods of the prior art have not provided a satisfactory solution for decreasing the thickness of a PCB.

It is an object of the present invention to provide a PCB whose thickness is less than a prior art PCB which comprises the same chips.

It is another object of the present invention to provide technologies for manufacturing a PCB, whose thickness is less than a prior art PCB which comprises the same chips.

Other objects and advantages of the invention will become apparent as the description proceeds.

### SUMMARY OF THE INVENTION

The present invention is directed to a printed circuit board, comprising: at least one chip; and a board comprising at least one aperture corresponding to each chip, for enabling each chip to be placed inside the corresponding aperture, thereby enabling reducing the thickness of the printed circuit board to that of the thickest chip. According to one embodiment of the invention, the chip is placed on the board with the upper side of the chip up. According to another embodiment of the invention, the chip is placed on the board with the upper side of the chip down. According to one embodiment of the invention the legs of the chip have “straight” form. According to another embodiment of the invention the legs of the chip have “bent” form.

### BRIEF DESCRIPTION OF THE DRAWINGS

The present invention may be better understood in conjunction with the following figures:

FIG. 1 illustrates a PCB, according to a preferred embodiment of the invention.

FIG. 2 is a “sliced” cross section of the board illustrated in FIG. 1.

FIG. 3 illustrates a cross section along the mounting region of chips 20 and 50 of FIG. 1.

FIG. 4 illustrates the PCB of FIG. 1, in an upside-down position.

FIG. 5 illustrates a cross section along the mounting region of chips 20 and 50 of FIG. 1 in a three-dimensional view.

FIG. 6 illustrates a chip having a “straight” form legs mounted on a board, according to the invention.

FIG. 7 illustrates a “bent” form legs mounted on a board, according to the invention.

FIG. 8 illustrates a “bent” form legs mounted on a board, according to another embodiment of the invention.

### DETAILED DESCRIPTION OF PREFERED EMBODIMENTS

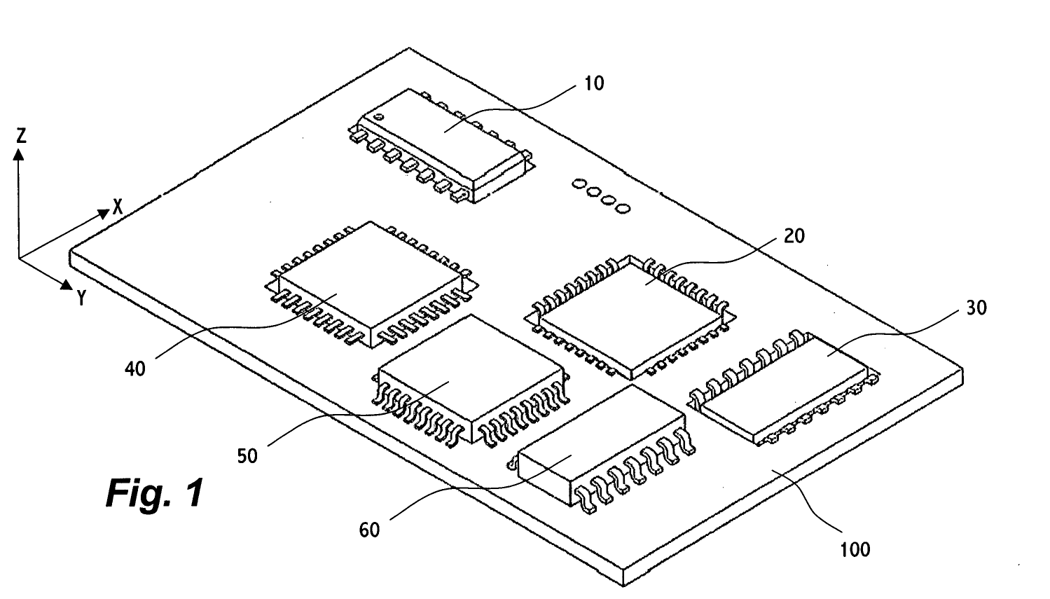

FIG. 1 illustrates a PCB, according to a preferred embodiment of the invention. Chips 10, 20, 30, 40, 50 and 60 are mounted on board 100.

In order to facilitate the text to follow, it should be noted that the width corresponds to the X axis, the length corresponds to the Y axis, and the thickness corresponds to the Z axis of the board. Thus, the thickness of a PCB is actually the thickest point of the PCB (i.e. along the Z axis).

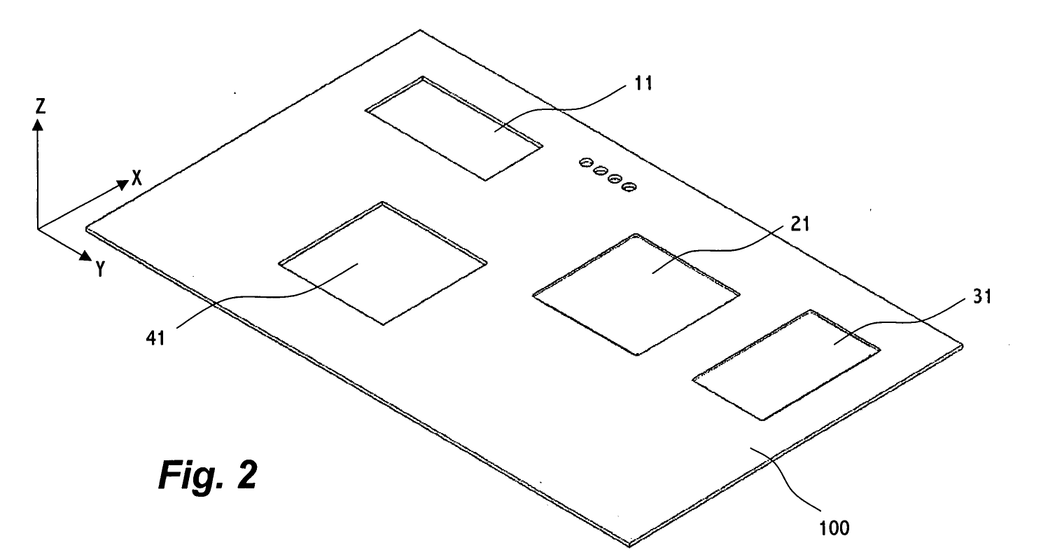

FIG. 2 is a “sliced” cross section of the board illustrated in FIG. 1. Apertures 11, 21, 31, and 41 correspond to the chips 10, 20, 30 and 40. Thus, when one of the chips 10 to 40 is mounted on the board 100, the corresponding aperture enables to mount the chip such that the size of the outstanding part of a chip is diminished by the thickness of the board 100.

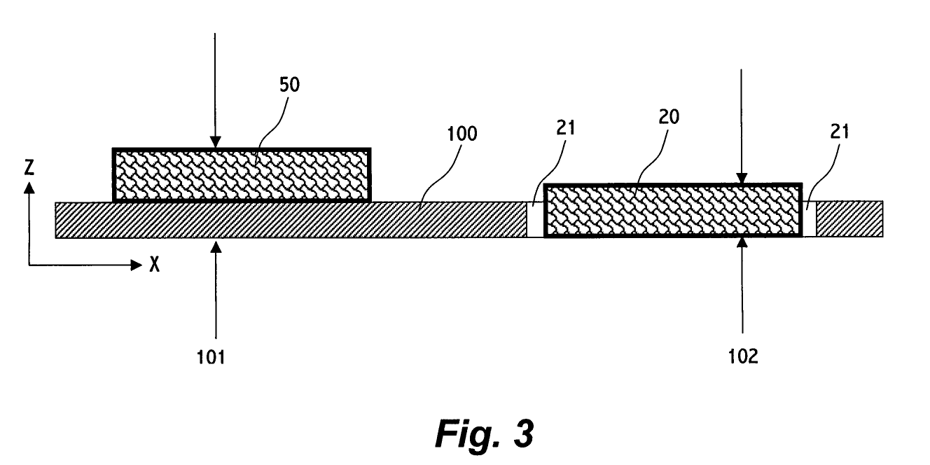

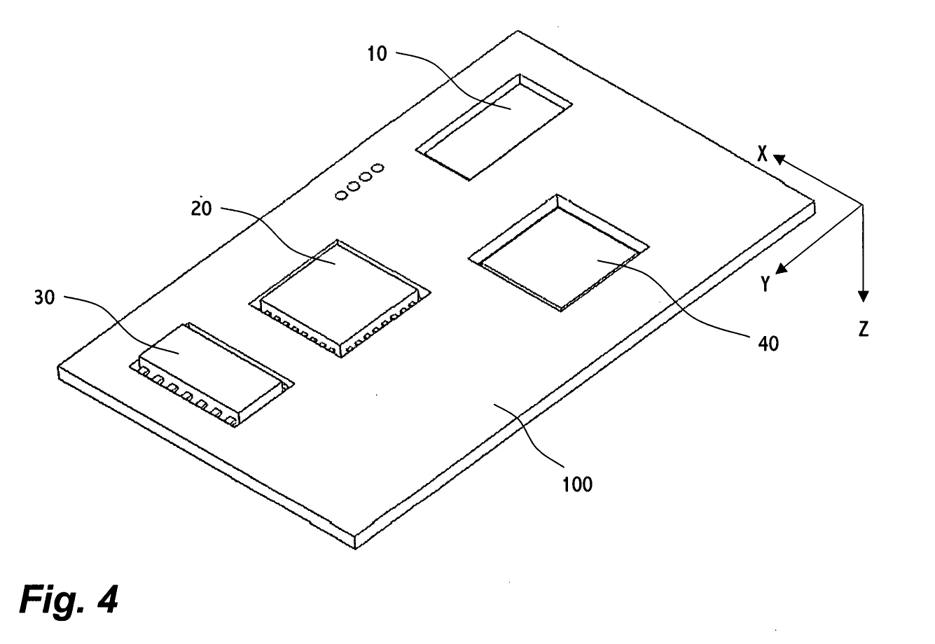

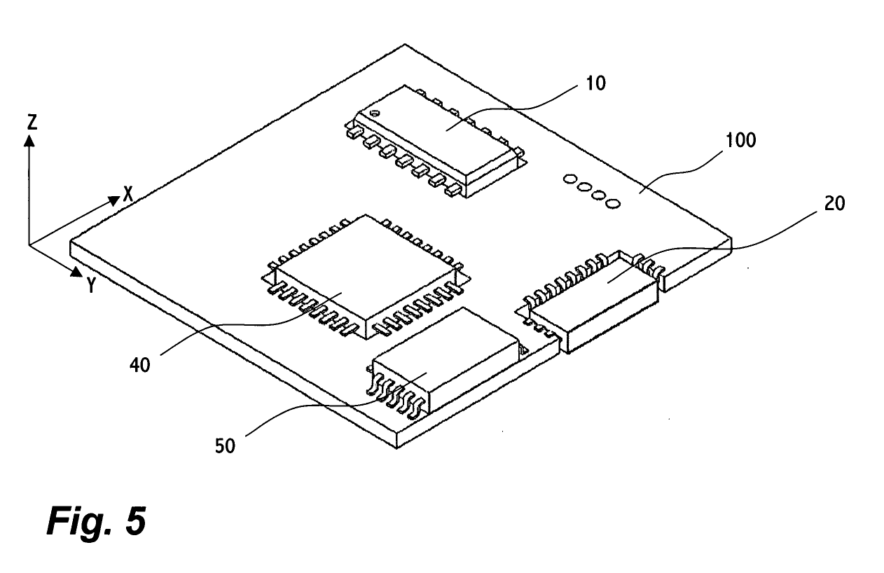

FIGS. 3 and 4 illustrate a cross section along the mounting regions of chips 20 and 50. Chip 50 is mounted according to the prior art, while chip 20 is mounted according to the present invention, i.e. into the aperture 21. The thickness 102, which is reflected from the fact that the chip 20 is inserted into the aperture 21, is less than the thickness 102.

The width and length of each aperture 11 to 41 is greater than the corresponding width and length of its corresponding chip, thereby allowing placing the chip inside the aperture. However, at least the width or the length of an aperture is smaller than the width or length of the corresponding chip including the chip's legs, thereby allowing the legs of the chips to contact the board 100.

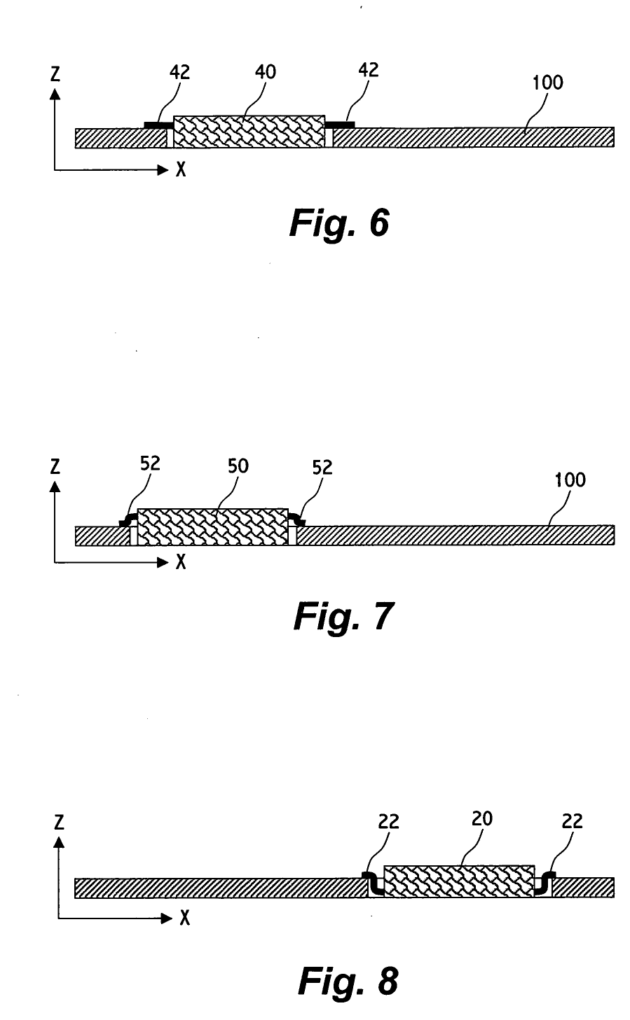

FIG. 6 illustrates a chip having a “straight” form legs mounted on a board, according to the invention. In FIG. 6 the legs 42 of chip 40 are parallel to the board 100.

FIG. 7 illustrates a “bent” form legs mounted on a board, according to the invention. The “bent” form of the legs is common in the chip industry.

FIG. 8 illustrates a “bent” form legs mounted on a board, according to another embodiment of the invention. The chip 20 is mounted in an upside-down position.

It should be noted that the legs of a chip may be manufactured to be flexible, thereby allowing mounting a chip on a board while pushing the chip towards the board, thereby bending its legs to the desired form.

Those skilled in the art will appreciate that the invention can be embodied in other forms and ways, without losing the scope of the invention. The embodiments described herein should be considered as illustrative and not restrictive.

1. A printed circuit board, comprising:
at least one chip;
a board comprising at least one aperture corresponding to said at least one chip, for enabling each said at least one chip to be placed inside said corresponding aperture thereof, thereby enabling reducing the thickness of said printed circuit board to the thickest of said at least one chip.

2. A printed circuit board according to claim 1, wherein said chip is placed on said board with the upper side of said chip up.

3. A printed circuit board according to claim 1, wherein said chip is placed on said bard with the upper side of said chip down.

4. A printed circuit board according to claim 1, wherein the legs of said chip have “straight” form.

5. A printed circuit board according to claim 1, wherein the legs of said chip have “bent” form.
